(19) United States
(12) Patent Application Publication
(10) Pub. No.: US 2025/0098155 A1
(43) Pub. Date: Mar. 20, 2025

(54) SEMICONDUCTOR DEVICE

(71) Applicant: Samsung Electronics Co., Ltd., Suwon-si (KR)

(72) Inventors: Minsung Kang, Suwon-si (KR); Hyoungyol Mun, Suwon-si (KR); Youngmin Lee, Suwon-si (KR)

(21) Appl. No.: 18/742,376

(22) Filed: Jun. 13, 2024

(30) Foreign Application Priority Data
Sep. 18, 2023 (KR) 10-2023-0124211

(51) Int. Cl. H10B 12/00

(52) U.S. Cl. CPC H10B 12/50; H10B 12/09; H10B 12/315

(57) ABSTRACT

A semiconductor device includes lower electrodes on a substrate, a support pattern between the lower electrodes, an upper electrode on the lower electrodes and the support pattern, and a dielectric layer between the lower electrodes and the upper electrode, and between the support pattern and the upper electrode. The upper electrode includes a first portion on upper surfaces of the lower electrodes and a second portion on a sidewall of the support pattern. The first portion is thicker than the second portion.

### CROSS-REFERENCE TO RELATED APPLICATIONS

This U.S. non-provisional patent application claims priority under 35 U.S.C. § 119 to Korean Patent Application No. 10-2023-0124211, filed on Sep. 18, 2023, in the Korean Intellectual Property Office, the entire contents of which are hereby incorporated by reference.

### FIELD

The inventive concept relates to a semiconductor device, and more specifically, relates to a semiconductor memory device including a capacitor.

### BACKGROUND

Semiconductor devices have become increasingly popular elements in the electronics industry, due for example to their small-size, multifunctionality, and low-cost characteristics. Semiconductor devices may include semiconductor memory devices for storing data, semiconductor logic devices for processing data, and hybrid semiconductor devices including both of memory and logic elements.

In view of demand for high speed and low power consumption of electronic devices, semiconductor devices in the electronic devices are being developed to provide high operating speeds and/or low operating voltages. Accordingly, there is demand for increased integration density of semiconductor devices. However, as the integration density of a semiconductor device increases, the semiconductor device may suffer from deterioration in electrical characteristics and/or production yield. Accordingly, studies are being conducted to improve the electrical characteristics and to increase the production yield of semiconductor devices.

### SUMMARY

Some embodiments of the inventive concept provide a semiconductor device with improved electrical characteristics.

Some embodiments of the inventive concept provide a semiconductor device with increased integration.

Embodiments of the inventive concepts are not limited to addressing the problems mentioned above, and other problems relating to or applications of embodiments described herein (even if not specifically mentioned) will be clearly understood by those skilled in the art from the description below.

A semiconductor device according to some embodiments of the inventive concept may include lower electrodes on a substrate, a support pattern between the lower electrodes, an upper electrode on the lower electrodes and the support pattern, and a dielectric layer between the lower electrodes and the upper electrode, and between the support pattern and the upper electrode. The upper electrode may include a first portion on upper surfaces of the lower electrodes and a second portion on a sidewall of the support pattern, and the first portion may be thicker than the second portion.

A semiconductor device according to some embodiments of the inventive concept may include lower electrodes on a substrate, a support pattern between the lower electrodes, an upper electrode on the lower electrodes and the support pattern, a dielectric layer between the lower electrodes and the upper electrode, and between the support pattern and the upper electrode, and a mask insulating pattern on the upper electrode opposite the lower electrodes and the support pattern. The upper electrode may include a first portion on upper surfaces of the lower electrodes and a second portion on a sidewall of the support pattern, and the mask insulating pattern may have a thickness that is thinner than a thickness of the first portion.

A semiconductor device according to some embodiments of the inventive concept may include active regions defined on a substrate by a device isolation layer, the active regions respectively comprising a first impurity region and a second impurity region, word lines on the active regions and extending in a first direction, capping insulating patterns on top surfaces of the word lines, respectively, bit lines on the word lines and extending in a second direction crossing the first direction, contact plugs between the bit lines and electrically connected to the second impurity region, and a capacitor on the contact plugs. The capacitor may include lower electrodes on the substrate, a support pattern between the lower electrodes, an upper electrode on the lower electrodes and the support pattern, and a dielectric layer provided between the lower electrodes and the upper electrode, and between the support pattern and the upper electrode. The upper electrode may include a first portion on upper surfaces of the lower electrodes and a second portion on a sidewall of the support pattern, and the first portion may be thicker than the second portion.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a semiconductor device according to embodiments of the inventive concept.

FIG. 2 is an enlarged view of region ‘P1’ in FIG. 1.

FIG. 3 is a cross-sectional view corresponding to A-A′ in FIG. 1.

FIGS. 4, 5, 6, 7, 8, 9, and 10 are cross-sectional views for illustrating a method of manufacturing a semiconductor device according to embodiments of the inventive concept.

FIG. 11 is a cross-sectional view of a semiconductor device according to embodiments of the inventive concept.

FIG. 12 is a cross-sectional view for illustrating a method of manufacturing a semiconductor device according to embodiments of the inventive concept.

FIG. 13 is a cross-sectional view of a semiconductor device according to embodiments of the inventive concept.

FIGS. 14 and 15 are cross-sectional views for illustrating a method of manufacturing a semiconductor device according to embodiments of the inventive concept.

### DETAILED DESCRIPTION OF EMBODIMENTS

Hereinafter, to explain the inventive concept in detail, embodiments according to the inventive concept will be described in detail with reference to the accompanying drawings. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

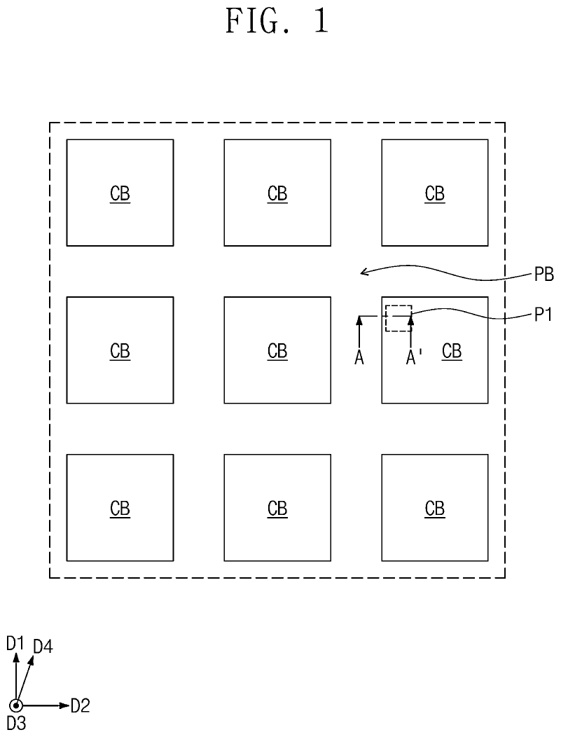

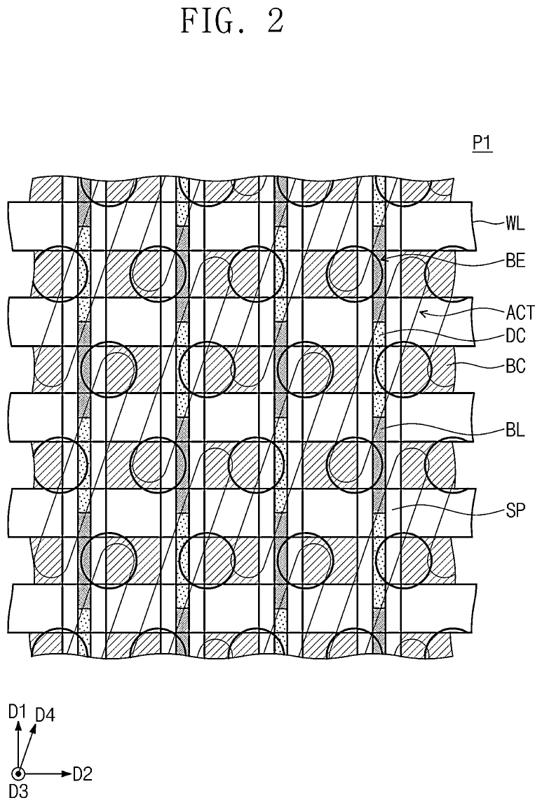

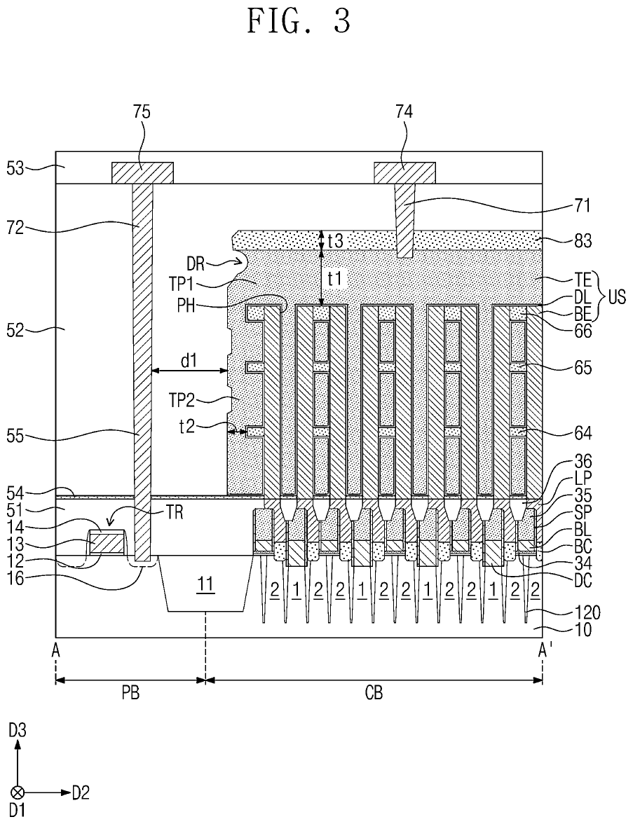

FIG. 1 is a plan view illustrating a semiconductor device according to embodiments of the inventive concept. FIG. 2 is an enlarged view of region ‘P1’ in FIG. 1. FIG. 3 is a cross-sectional view corresponding to region A-A′ in FIG. 1.

Referring to FIG. 1, a semiconductor device may include cell regions CB and a peripheral circuit region PB extending around or surrounding each of the cell regions CB. The semiconductor device may be a memory device, and each of the cell regions CB may include a cell circuit such as a memory integrated circuit. The cell regions CB may be spaced apart from each other in a first direction D1 and a second direction D2 that intersects (e.g., is perpendicular to) the first direction D1. For example, the first direction D1 and the second direction D2 may be horizontal or lateral directions.

The peripheral circuit region PB may include various peripheral circuits that may be necessary for operation of the cell circuits, and the peripheral circuits may be electrically connected to the cell circuits. The peripheral circuit region PB may include sense amplifier circuits and sub-word line driver circuits. For example, the sense amplifier circuits may face each other with the cell regions CB therebetween, and the sub-word line driver circuits may face each other with the cell regions CB therebetween. The peripheral circuit region PB may further include power and ground driver circuits for driving the sense amplifier, but the inventive concept is not limited thereto.

Referring to FIGS. 2 and 3, a substrate 10 including a cell region CB and a peripheral circuit region PB may be provided. The cell region CB may be an region of the substrate 10 where each cell region CB of FIG. 1 is provided. The substrate 10 may be, for example, a silicon substrate, a germanium substrate, or a silicon-germanium substrate.

Active patterns ACT may be disposed on the cell region CB of the substrate 10. When viewed in a plan view, the active patterns ACT may be spaced apart from each other in the first direction D1 and the second direction D2. The active patterns ACT may be parallel to an upper surface of the substrate 10 and may have a bar shape extending in a fourth direction D4 that intersects the first direction D1 and the second direction D2. An end of one of the active patterns ACT may be arranged to be adjacent to a center of another active pattern ACT that is immediately adjacent thereto in the second direction D2. Each of the active patterns ACT may be a portion of the substrate 10 that protrudes from the substrate 10 in the third direction D3 (e.g., in a vertical direction).

First device isolation layers 120 may be disposed between the active patterns ACT. The first device isolation layers 120 may be disposed in the substrate 10 to define the active patterns ACT. For example, the first device isolation layers 120 may include silicon oxide, silicon nitride, and/or silicon oxynitride.

Word lines WL may be disposed in the substrate 10 and may cross the active patterns ACT and the first device isolation layers 120. The word lines WL may be disposed in grooves formed in the active patterns ACT and the first device isolation layers 120. The word lines WL may extend in the second direction D2 and be spaced apart from each other in the first direction D1. The word lines WL may be buried in the substrate 10.

Impurity regions may be provided in the active patterns ACT. The impurity regions may include first impurity regions 1 and second impurity regions 2. The second impurity regions 2 may be provided adjacent to both (e.g., opposing) ends of each of the active patterns ACT. Each of the first impurity regions 1 may be provided between the second impurity regions 2 in each of the active patterns ACT. The first impurity regions 1 may include impurities of the same conductivity type (e.g., N-type) as the second impurity regions 2.

A buffer pattern 34 may be disposed on the cell region CB of the substrate 10. The buffer pattern 34 may cover the active patterns ACT, the first device isolation layers 120, and the word lines WL. For example, the buffer pattern 34 may include silicon oxide, silicon nitride, and/or silicon oxynitride.

Bit lines BL may be disposed on the substrate 10. The bit lines BL may extend in the first direction D1 and may be spaced apart from each other in the second direction D2. Each of the bit lines BL may include an ohmic pattern and a metal-containing pattern that are sequentially stacked. As an example, the ohmic pattern may include metal silicide. As an example, the metal-containing pattern may include metal (tungsten, titanium, tantalum, etc.). Polysilicon patterns may be interposed between the bit lines BL and the buffer pattern 34.

Bit line contacts DC may be interposed on each of the first impurity regions 1. The bit lines BL may be electrically connected to the first impurity regions 1 through the bit line contacts DC. The bit line contacts DC may include polysilicon doped with impurities or undoped polysilicon.

The bit line contacts DC may be disposed in the recess region. The recess region may be provided in upper portion of the first impurity regions 1 and in an upper portion of the first device isolation layers 120 adjacent thereto.

A bit line capping pattern 35 may be provided on an upper surface of each of the bit lines BL. The bit line capping pattern 35 may extend in the first direction D1 on each of the bit lines BL, and may be spaced apart from neighboring bit line capping patterns 35 in the second direction D2. The bit line capping pattern 35 may include a silicon nitride layer.

A bit line spacer SP may be provided on each side of the bit line contacts DC and the bit lines BL. The bit line spacer SP may extend in the first direction D1 along each of the bit lines BL. The bit line spacer SP may include a plurality of insulating layers. As an example, the bit line spacer SP may include a silicon oxide layer and a silicon nitride layer. The bit line spacer SP may include an air gap, which is a substantially empty space, therein.

Storage node contacts BC may be interposed between neighboring bit lines BL on the substrate 10. The bit line spacer SP may be interposed between the storage node contacts BC and the bit lines BL adjacent thereto. The storage node contacts BC may be spaced apart from each other in the first direction D1 and the second direction D2. Each of the storage node contacts BC may be electrically connected to a corresponding one of the second impurity regions 2. The storage node contacts BC may include polysilicon doped with impurities or undoped polysilicon.

Landing pads LP may be disposed on each of the storage node contacts BC. Each of the landing pads LP may be electrically connected to a corresponding one of the storage node contacts BC. The landing pads LP may include a metal-containing material such as tungsten. Upper portions of the landing pads LP may be shifted or offset from the storage node contacts BC in the second direction D2. When viewed in a plan view, the landing pads LP may be spaced apart from each other in the first direction D1 and the second direction D2. For example, the landing pads LP may be spaced apart from each other in the first direction D1 and the second direction D2 in a zigzag shape.

An ohmic pattern may be provided between landing pads LP and the storage node contacts BC. The ohmic pattern may include metal silicide.

A filling pattern 36 may surround each of the landing pads LP. The filling pattern 36 may be interposed between adjacent landing pads LP. As an example, the filling pattern 36 may include at least one of silicon nitride, silicon oxide, or silicon oxynitride. As another example, the filling pattern 36 may include an empty region (e.g., an air gap or other void).

The cell region CB and the peripheral circuit region PB may be spaced apart from each other by a second device isolation layer 11 formed on the substrate 10. For example, the second device isolation layer 11 may include silicon oxide, silicon nitride, and/or silicon oxynitride. A peripheral transistor TR may be provided in the peripheral circuit region PB. The peripheral transistor TR may be a transistor constituting sense amplifier circuits or sub-word line driver circuits. The peripheral transistor TR may include a gate electrode 13, a gate insulating layer 12, source/drain regions 16, and a gate capping pattern 14.

A first interlayer insulating layer 51 may be provided on or covering the peripheral transistor TR. The term “covering” or “surrounding” or “filling” as may be used herein may not require completely covering or surrounding or filling the described elements or layers, but may, for example, refer to partially surrounding or covering or filling the described elements or layers, for example, with voids or other spaces throughout. The first interlayer insulating layer 51 may include a silicon oxide layer. The first interlayer insulating layer 51 may include silicon oxide, silicon nitride, and/or silicon oxynitride. The first interlayer insulating layer 51 may extend into the cell region CB.

An etch stop pattern 54 may be disposed on the filling pattern 36. The etch stop pattern 54 may expose upper surfaces of the landing pads LP. The term “exposed” may be used to describe relationships between elements and/or certain intermediate processes in fabricating a completed semiconductor device, but may not necessarily require exposure of the particular region, layer, structure or other element in the context of the completed device. The etch stop pattern 54 may include at least one of silicon nitride, silicon carbonitride, or silicon oxynitride. The etch stop pattern 54 may extend into the peripheral circuit region PB and may cover the first interlayer insulating layer 51.

Lower electrodes BE may be disposed on each of the upper surfaces of the landing pads LP. Each of the lower electrodes BE may be electrically connected to a corresponding one of the landing pads LP. The lower electrodes BE may penetrate the etch stop pattern 54. For example, each of the lower electrodes BE may have a pillar shape. As another example, although not illustrated, each of the lower electrodes BE may have a cylinder shape with a closed bottom surface.

The lower electrodes BE may be spaced apart from each other in the first direction D1 and the second direction D2. As illustrated in FIG. 2, the lower electrodes BE may be arranged to have a honeycomb shape in plan view. In detail, with one lower electrode BE at a center, six lower electrodes BE may be arranged to surround the one lower electrode BE in a hexagon. The lower electrodes BE may include a conductive material. For example, the lower electrodes BE may include at least one of a metal material (e.g., cobalt, titanium, nickel, tungsten, and molybdenum), a metal nitride (e.g., titanium nitride (TiN), titanium silicon dioxide (TiSiN), titanium aluminum nitride (TiAIN), tantalum nitride (TaAIN), and tungsten nitride (WN)), a precious metal (e.g., platinum (Pt), ruthenium (Ru), and iridium (Ir)), a conductive oxide (PtO, RuO₂, IrO₂, SrRuO₃ (SRO), (Ba,Sr)RuO₃ (BSRO), CaRuO₃ (CRO), LSCo), or a metal silicide.

Support patterns may be provided on the substrate 10. The support patterns may include a first support pattern 64, a second support pattern 65, and a third support pattern 66 spaced apart from each other in the third direction D3. Although three support patterns are described as being provided, fewer or more support patterns may be provided. The first support pattern 64, the second support pattern 65, and the third support pattern 66 may be sequentially arranged in the third direction D3. Each of the support patterns 64, 65, and 66 may include, for example, at least one of silicon nitride, SiBN, or SiCN. The third support pattern 66 may be thicker than the first support pattern 64 and the second support pattern 65. However, in contrast, the first support pattern 64, the second support pattern 65, and the third support pattern 66 may have the same thickness.

When viewed in a plan view, each of the support patterns 64, 65, and 66 may be interposed between one of the lower electrodes BE and a neighboring lower electrode BE. Each of the support patterns 64, 65, and 66 may be provided on sidewalls of the lower electrodes BE. Each of the support patterns 64, 65, and 66 may include penetrating holes PH exposing portions of sidewalls of the lower electrodes BE. As an example, one penetrating hole PH may be arranged in a circular shape between three adjacent lower electrodes BE, and may expose a portion of a side surface of each of the three lower electrodes BE. However, the inventive concept is not limited thereto, and the penetrating holes PH may be arranged between the plurality of lower electrodes BE in various shapes.

An upper electrode TE may cover the lower electrodes BE and the support patterns 64, 65, and 66. A dielectric layer DL may be interposed between the lower electrodes BE and the upper electrode TE, and between the support patterns 64, 65, and 66 and the upper electrode TE. The dielectric layer DL may conformally cover the lower electrodes BE and the support patterns 64, 65, and 66. The dielectric layer DL may cover an upper surface of the etch stop pattern 54 in the cell region DB. The dielectric layer DL may have the same crystal structure as that of the lower electrodes BE. For example, the dielectric layer DL may have a tetragonal structure. The dielectric layer DL may be formed of a single layer selected from a combination of dielectric materials, for example, a metal oxide such as HfO₂, ZrO₂, Al₂O₃, La₂O₃, Ta₂O₃, and TiO₂, and a perovskite-structured dielectric material such as SrTiO₃ (STO), (Ba,Sr)TiO₃ (BST), BaTiO₃, PZT, and PLZT, or a combination of these layers.

The upper electrode TE may cover the lower electrodes BE and the support patterns 64, 65, and 66. The upper electrode TE may fill a space between the lower electrodes BE, through the penetrating holes PH. The upper electrode TE may include at least one of titanium nitride, polysilicon doped with impurities, and silicon germanium doped with impurities. The upper electrode TE may be a single layer or a multilayer. The lower electrodes BE, the dielectric layer DL, and the upper electrode TE may form a capacitor US. As an example, the capacitor US may function as a data storage element for the semiconductor device according to the inventive concept to operate as a memory device.

A mask insulating pattern 83 may be provided on or covering the upper electrode TE. The mask insulating pattern 83 may be provided in the cell region CB and may not be provided in the peripheral circuit region PB. The mask insulating pattern 83 may include at least one of SiON, SIN, or TEOS. The mask insulating pattern 83 may be in contact with an upper surface of the upper electrode TE.

A second interlayer insulating layer 52 may be provided on or covering the mask insulating pattern 83. The second interlayer insulating layer 52 may be provided on the first interlayer insulating layer 51 in the peripheral circuit region PB. A third interlayer insulating layer 53 may be provided on the second interlayer insulating layer 52. The second interlayer insulating layer 52 and the third interlayer insulating layer 53 may include silicon oxide, silicon nitride, and/or silicon oxynitride.

A cell contact plug 71 may be provided that penetrates the second interlayer insulating layer 52 and is connected to the top of the upper electrode TE. The cell contact plug 71 may penetrate the mask insulating pattern 83. Although only one cell contact plug 71 is illustrated, a plurality of cell contact plugs 71 may be provided. A peripheral contact plug 72 may be provided that penetrates the first interlayer insulating layer 51 and the second interlayer insulating layer 52 and is connected to the peripheral transistor TR. For example, the peripheral contact plug 72 may be connected to the source/drain region 16 of the peripheral transistor TR. Alternatively, the peripheral contact plug 72 may be connected to the gate electrode 13 of the peripheral transistor TR. The peripheral contact plug 72 may penetrate the etch stop pattern 54. The peripheral contact plug 72 and the cell contact plug 71 may include a metal layer and a metal nitride layer. For example, the peripheral contact plug 72 and the cell contact plug 71 may include tungsten, titanium, tantalum, and/or nitride layers thereof. The peripheral contact plug 72 and the cell contact plug 71 may have a shape whose width decreases as the peripheral contact plug 72 and the cell contact plug 71 approach the substrate 10.

A first wiring 74 connected to the cell contact plug 71 and a second wiring 75 connected to the peripheral contact plug 72 may be provided in or on the second interlayer insulating layer 52. For example, the first wiring 74 and the second wiring 75 may include copper or aluminum.

Hereinafter, the upper electrode TE and a structure adjacent thereto will be described in detail.

The upper electrode TE may include a first portion TP1 on or covering upper surfaces of the lower electrodes BE and a second portion TP2 on or covering sidewalls of the support patterns 64, 65, and 66. The second portion TP2 may be a portion between the peripheral contact plug 72 and the support patterns 64, 65, and 66. The first portion TP1 may include a dent region DR in an region adjacent to the peripheral circuit region PB. The dent region DR may extend below the mask insulating pattern 83. For example, the dent region DR may be region of the upper electrode TE having a concave shape that undercuts the mask insulating pattern 83. The second portion TP2 may include an uneven structure having a non-uniform thickness on a sidewall thereof, and the uneven structure may be due to the support patterns 64, 65, and 66. In contrast, the uneven structure may not be provided.

A thickness t1 of the first portion TP1 may be thicker than a thickness t2 of the second portion TP2. For example, the thickness t2 of the second portion TP2 may be about 50% to about 90% of the thickness t1 of the first portion TP1. For example, the thickness t1 of the first portion TP1 may be about 2000 Å to about 3000 Å, and the thickness t2 of the second portion TP2 may be about 1500 Å to about 2500 Å. A thickness t3 of the mask insulating pattern 83 may be smaller than the thickness t1 of the first portion TP1. The thickness t3 of the mask insulating pattern 83 may be smaller than the thickness t2 of the second portion TP2. Alternatively, the thickness t3 may be greater than the thickness t2 of the second portion TP2 and may be smaller than the thickness t1 of the first portion TP1.

A distance d1 between the peripheral contact plug 72 and the second portion TP2 may be greater than the thickness t1 of the first portion TP1. This is because the thickness t2 of the second portion TP2 is formed to be thinner, that is, thinner than the thickness t1 of the first portion TP1, through a process to be described below. When the distance between the peripheral contact plug 72 and the second portion TP2 is relatively small, a short circuit may occur between the peripheral contact plug 72 and the upper electrode TE or a leakage current may occur therebetween. According to embodiments of the inventive concept, a separation distance d1 between the peripheral contact plug 72 and the upper electrode TE may be secured or increased, thereby improving electrical characteristics of the semiconductor device and increasing integration thereof.

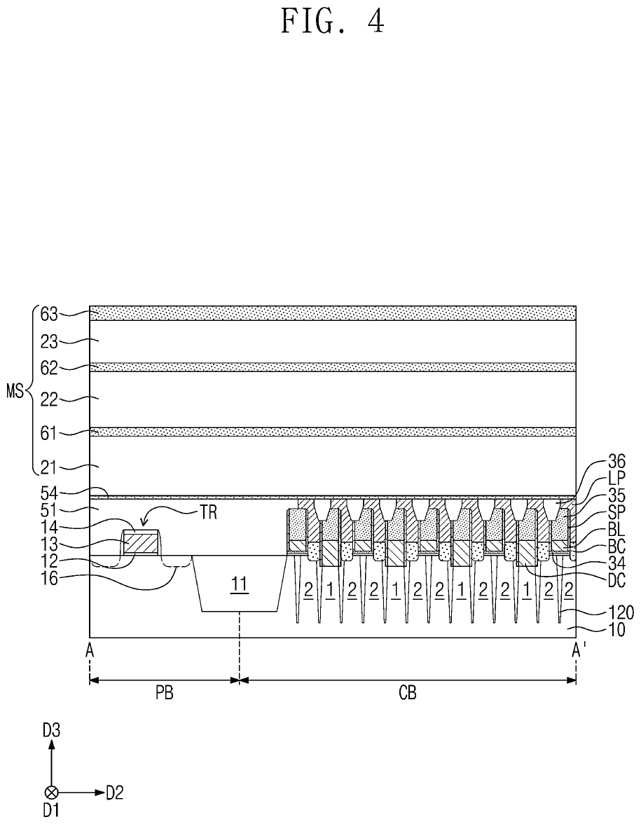

FIGS. 4 to 10 are cross-sectional views for illustrating a method of manufacturing a semiconductor device according to embodiments of the inventive concept. To simplify explanation, descriptions of configurations identical or similar to those previously described may be omitted.

Referring to FIG. 4, a substrate 10 including a cell region CB and a peripheral circuit region PB may be provided. The substrate 10 may be a semiconductor substrate. The substrate 10 may be, for example, a silicon substrate, a germanium substrate, or a silicon-germanium substrate. First device isolation layers 120 may be formed on the cell region CB, and a second device isolation layer 11 may be formed between the cell region CB and the peripheral circuit region PB. Bit line contacts DC, bit lines BL, storage node contacts BC, bit line capping patterns 35, and landing pads LP may be formed on the cell region CB. A peripheral transistor TR may be formed on the peripheral circuit region PB.

A first interlayer insulating layer 51 and an etch stop pattern 54 on or covering the cell region CB and the peripheral circuit region PB may be formed. The etch stop pattern 54 may be disposed on the first interlayer insulating layer 51. The etch stop pattern 54 may include at least one of silicon oxide, SiCN, or SiBN.

A mold structure MS may be formed on the etch stop pattern 54. The mold structure MS may be formed by alternately stacking mold layers and support layers. As an example, the mold structure MS may include a first mold layer 21, a first support layer 61, a second mold layer 22, a second support layer 62, and a third mold layer 23, and a third support layer 63 that are sequentially stacked. The first to third mold layers 21, 22, and 23 may include a material that has etch selectivity with respect to the first to third support layers 61, 62, and 63 and may be selectively removed. The first to third mold layers 21, 22, and 23 may include the same material. The first to third support layers 61, 62, and 63 may include the same material. As an example, the first to third mold layers 21, 22, and 23 may include silicon oxide. The first to third support layers 61, 62, and 63 may include at least one of silicon nitride, SiBN, or SiCN.

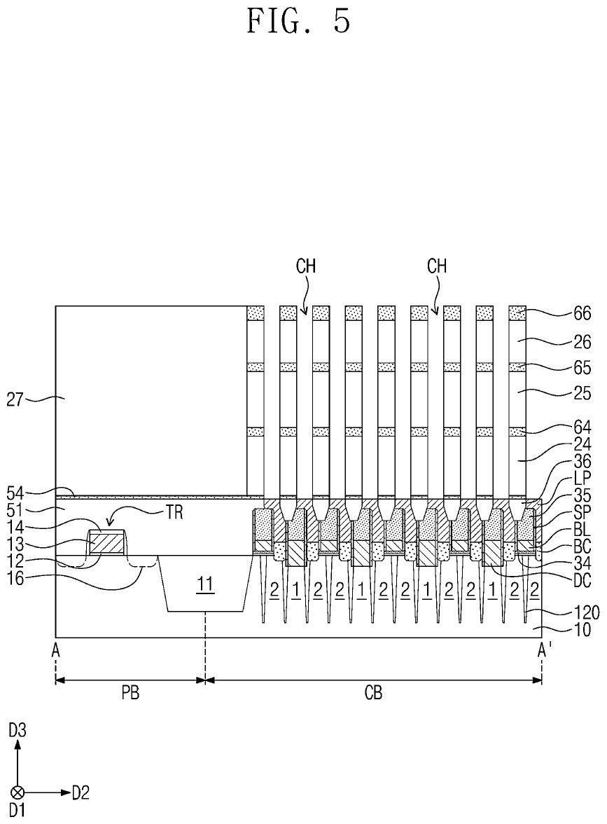

Referring to FIG. 5, after removing the mold structure MS on the peripheral circuit region PB, a fourth mold pattern 27 may be formed. The fourth mold pattern 27 may be formed of the same material as the first to third mold layers 21, 22, and 23. Afterwards, the mold structure MS on the cell region CB may be patterned to form penetrating holes CH. A shape of the penetrating holes CH may be circular when viewed in a plan view, but is not limited thereto. As the penetrating holes CH may be formed, the first to third mold layers 21, 22, and 23 may become first to third mold patterns 24, 25, and 26, the first to third mold layers 21, 22, and 23 may become first to third mold patterns 24, 25, and 26, and the support layers 61, 62, and 63 may become first to third support patterns 64, 65, and 66.

Forming the penetrating holes CH may include a dry etching process using a mask pattern including openings. The mask pattern may include at least one of polysilicon, silicon nitride, or silicon oxynitride. The penetrating holes CH may be formed to penetrate the etch stop pattern 54. As a result, each of the penetrating holes CH may expose upper surfaces of the landing pads LP.

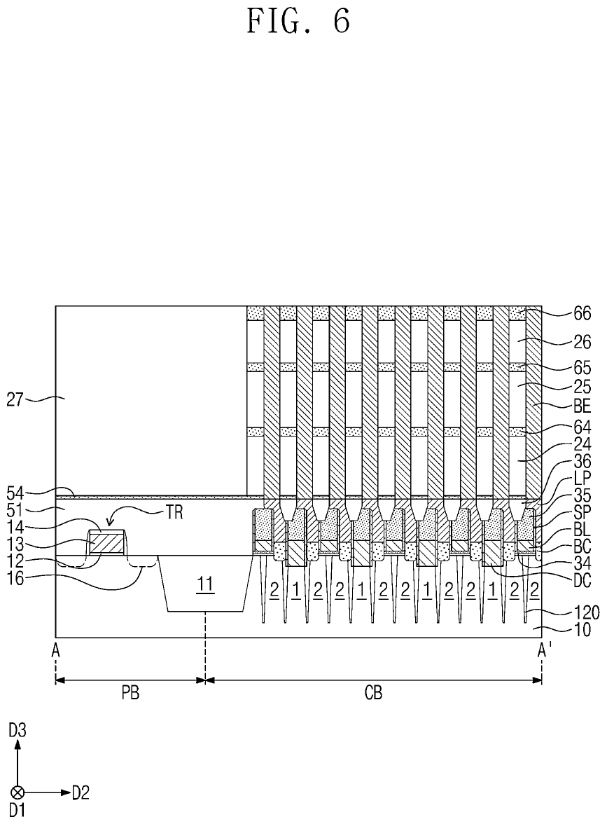

Referring to FIG. 6, lower electrodes BE may be formed in the penetrating holes CH. Forming the lower electrodes BE may include forming an electrode layer that fills the penetrating holes CH. The electrode layer may be formed through a deposition technology with excellent step coverage. As an example, the electrode layer may be formed through a chemical vapor deposition (CVD) or atomic layer deposition (ALD) process.

As an example, the electrode layer may be formed to completely fill the penetrating holes CH. As another example, although not illustrated, the electrode layer may be formed to conformally cover an inner wall of each of the penetrating holes CH and an upper surface of the mold structure MS. The electrode layer may include at least one of a metal material (e.g., cobalt, titanium, nickel, tungsten, and molybdenum), a metal nitride (e.g., titanium nitride (TiN), titanium silicon dioxide (TiSiN), titanium aluminum nitride (TiAIN), tantalum nitride (TaAIN), and tungsten nitride (WN)), a precious metal (e.g., platinum (Pt), ruthenium (Ru), and iridium (Ir)), a conductive oxide (PtO, RuO₂, IrO₂, SrRuO₃ (SRO), (Ba,Sr)RuO₃ (BSRO), CaRuO₃ (CRO), LSCo), or metal silicide.

Afterwards, an upper portion of the electrode layer may be removed and separated into lower electrodes BE that fill each of the penetrating holes CH. Removing the upper portion of the electrode layer may include, for example, performing an etch-back process. The lower electrodes BE may each be connected to upper surfaces of the landing pads LP. Although not illustrated, when the electrode layer is formed to conformally cover the inner wall of each of the penetrating holes CH, each of the lower electrodes BE may be formed to have a cylinder shape with a closed bottom surface.

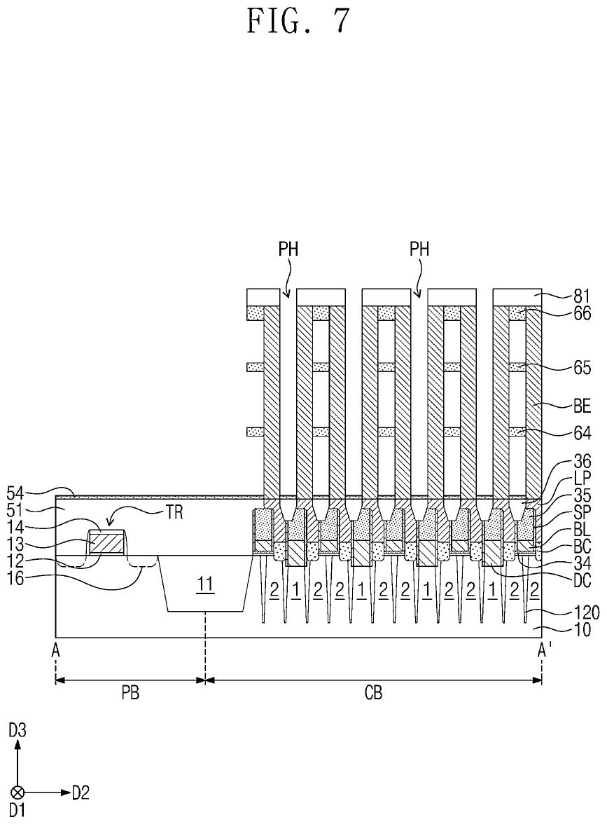

Referring to FIG. 7, after forming a mask pattern 81 exposing a portion of an upper surface of the third support pattern 66, the third support pattern 66 may be patterned using the mask pattern 81 to form penetrating holes PH. As a result, the upper surface of the third mold pattern 26 may be exposed. The third mold pattern 26 with the upper surface thereof exposed may be selectively removed, and thus a portion of an upper surface of the second support pattern 65 may be exposed. Afterwards, the penetrating holes PH may be formed in the exposed portion of the second support pattern 65, and accordingly the exposed second mold pattern 25 may be selectively removed. Likewise, the penetrating holes PH may be formed in the first support pattern 64 exposed by removing the second mold pattern 25, and accordingly the exposed first mold pattern 24 may be selectively removed. The fourth mold pattern 27 may be removed together with the first to third mold patterns 24, 25, and 26.

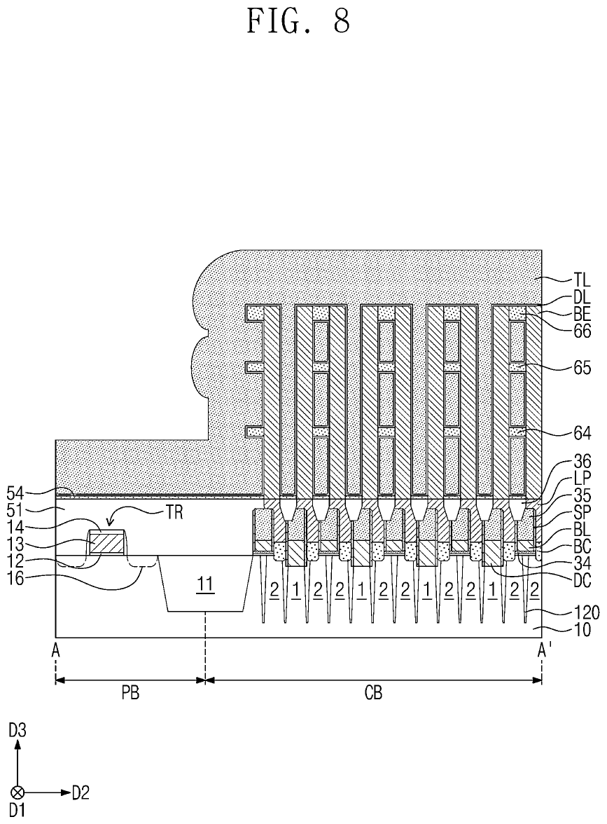

Referring to FIG. 8, after removing the mask pattern 81, a dielectric layer DL and an upper electrode layer TL may be formed sequentially. The dielectric layer DL may cover the exposed surfaces of the lower electrodes BE and the first to third support patterns 64, 65, and 66. The dielectric layer DL may extend into the peripheral circuit region PB and cover the etch stop pattern 54. The upper electrode layer TL may cover upper surfaces of the lower electrodes BE in the cell region CB and may extend to the peripheral circuit region PB. The upper electrode layer TL may fill the space between the lower electrodes BE and the first to third support patterns 64, 65, and 66. The upper electrode layer TL may be formed on the dielectric layer DL. The upper electrode layer TL may be formed of either polysilicon doped with impurities or silicon germanium doped with impurities. The upper electrode layer TL may conformally extend on and may cover sidewalls of the first to third support patterns 64, 65, and 66 and sidewalls of the lower electrodes BE between the cell region CB and the peripheral circuit region PB. The upper electrode layer TL may include an uneven structure having a non-uniform thickness, including protruding regions that are not flat due to the conformal extension on the sidewalls of the first to third support patterns 64, 65, and 66.

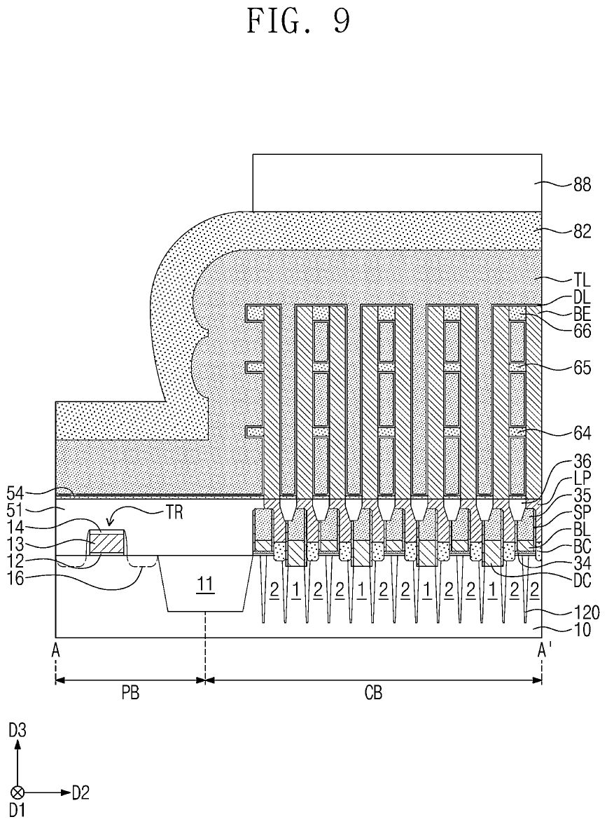

Referring to FIG. 9, after forming a mask insulating layer 82 on the upper electrode layer TL, a photoresist pattern 88 on or covering the cell region CB may be formed. The mask insulating layer 82 may be formed of at least one of SiON, SIN, or TEOS.

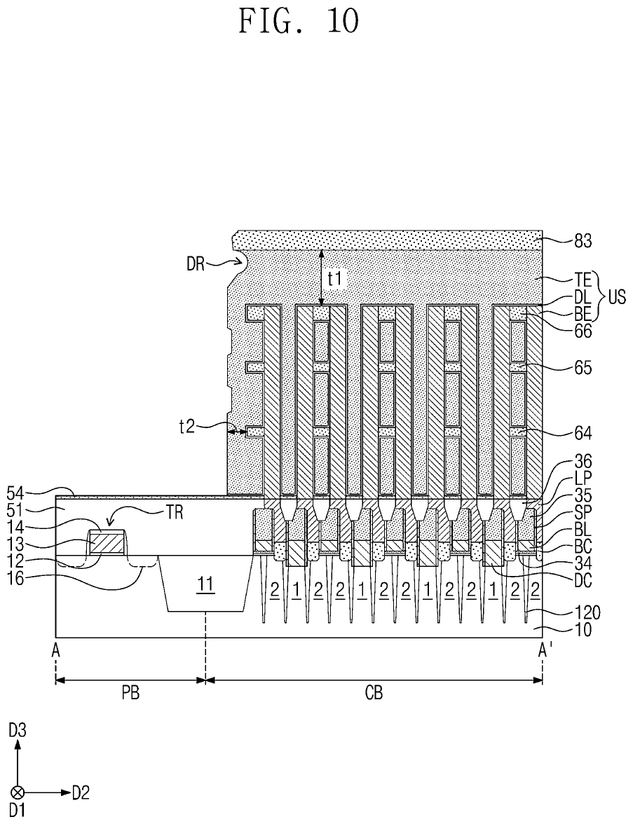

Referring to FIG. 10, the mask insulating layer 82 may be patterned using the photoresist pattern 88 as an etch mask to form the mask insulating pattern 83. Afterwards, an etching process may be performed on the upper electrode layer TL formed on the peripheral circuit region CB using the mask insulating pattern 83 as an etch mask to form a upper electrode TE.

The etching process of the upper electrode layer TL may include a dry etching process. During the dry etching process, the photoresist pattern 88 may be removed and an upper portion of the mask insulating pattern 83 may also be removed. The etching process of the upper electrode layer TL may include a wet cleaning process after the dry etching process. The cleaning process may be performed with at least one of SCI, diluted sulfuric peroxide (DSP), potassium hydroxide (KOH), and tetra methyl ammonium hydroxide (TMAH). By the dry etching process and the cleaning process, a thickness t2 of the upper electrode layer TL on the sidewalls of the first to third support patterns 64, 65, and 66 may be reduced to be thinner than a thickness t1 of the upper electrode layer TL on the lower electrodes BE. Additionally, a dent region DR having a concave shape may be formed on a sidewall of the upper electrode TE in an region adjacent to the peripheral circuit region PB. When forming the upper electrode TE, the dielectric layer DL on the peripheral circuit region PB may be removed together.

In another embodiment, the etching process of the upper electrode layer TL may include a wet etching process. The photoresist pattern 88 may be removed after the wet etching process. The etching process of the upper electrode layer TL may include a wet cleaning process after the wet etching process. As in the case of a dry etching process, the dent region DR may be formed on the sidewall of the upper electrode TE in an region adjacent to the peripheral circuit region PB.

Referring again to FIG. 3, a second interlayer insulating layer 52 may be provided on or covering the cell region CB and the peripheral circuit region PB. A cell contact plug 71 may be formed through the second interlayer insulating layer 52 and the mask insulating pattern 83 and connected to the upper electrode TE. A peripheral contact plug 72 may be formed through the second interlayer insulating layer 52 and the first interlayer insulating layer 51 and connected to the peripheral transistor TR. The cell contact plug 71 and the peripheral contact plug 72 may be formed together of the same material, but are not limited thereto.

After forming first and second wirings 74 and 75 respectively connected to the cell contact plug 71 and the peripheral contact plug 72, a third interlayer insulating layer 53 may be formed to cover the first and second wirings 74 and 75.

To reduce a thickness of the second portion TP2 of the upper electrode TE, a thickness of the first portion TP1 may be reduced together, and excessive damage may occur in the first portion TP1 adjacent to the peripheral circuit region PB. In the case of the manufacturing method according to embodiments of the inventive concept, a thickness t2 of the sidewall (or the second portion TP2) of the upper electrode TE may be selectively reduced (i.e., without substantially reducing a thickness t1 of the top or first portion TP1), and thus a separation distance between the peripheral contact plug 72 and the upper electrode TE may be secured or increased, thereby increasing integration of the semiconductor device.

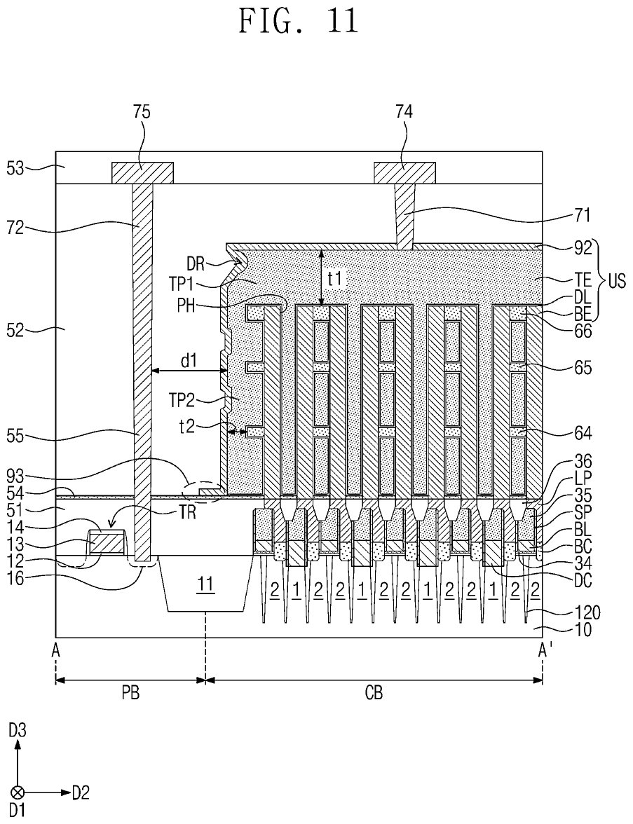

FIG. 11 is a cross-sectional view of a semiconductor device according to embodiments of the inventive concept. To simplify explanation, descriptions of configurations that are identical or similar to those previously described may be omitted.

Referring to FIG. 11, a capacitor US may include a metal layer 92 on or covering the upper electrode TE and conformally extending thereon. As an example, the metal layer 92 may cover the first portion TP1 and the second portion TP2 of the upper electrode TE. The metal layer 92 may include a protrusion 93 extending from the second portion TP2 toward the peripheral circuit region PB. The protrusion 93 may be in contact with the etch stop pattern 54. Alternatively, the protrusion 93 may be in contact with the first interlayer insulating layer 51. The metal layer 92 may fill the dent region DR. The metal layer 92 may include a metal material such as tungsten. The metal layer 92 may include a convex portion in the dent region DR, and may be thinner than the thickness t2 of the second portion TP2 of the upper electrode TE.

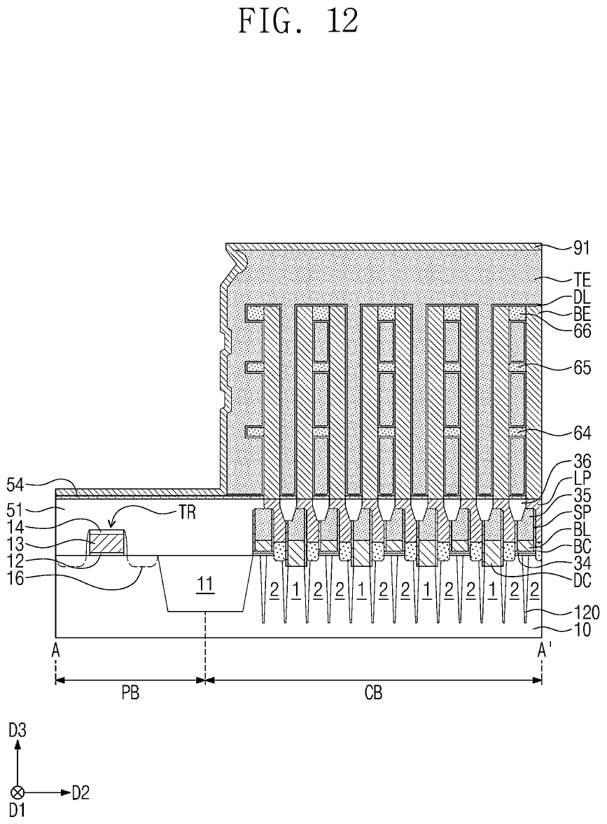

FIG. 12 is a cross-sectional view for illustrating a method of manufacturing a semiconductor device according to embodiments of the inventive concept.

Referring to FIG. 12, the mask insulating pattern 83 may be removed from the result described with reference to FIG. 10. The mask insulating pattern 83 may be selectively removed through a wet etching process. After removing the mask insulating pattern 83, a preliminary metal layer 91 on or covering the upper electrode TE may be formed. The preliminary metal layer 91 may be formed on the cell region CB and the peripheral circuit region PB, and may extend onto the etch stop pattern 54 in the peripheral circuit region PB.

Referring again to FIG. 11, patterning of the preliminary metal layer 91 may be performed to form the metal layer 92. Patterning of the preliminary metal layer 91 may include performing a mask pattern forming process and a dry etching process. Afterwards, the process of forming the cell contact plug 71, the peripheral contact plug 72, the first wiring 74, and the second wiring 75 described with reference to FIG. 3 may be performed.

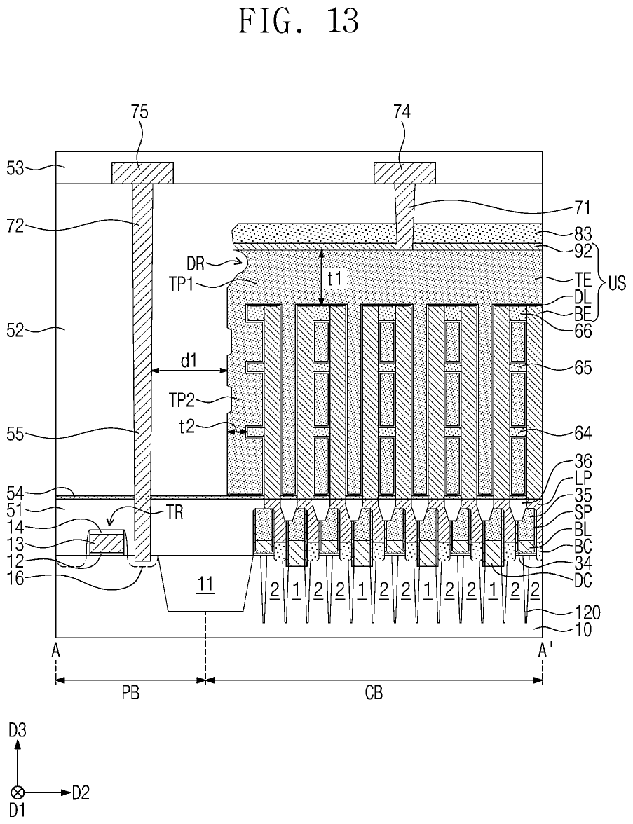

FIG. 13 is a cross-sectional view of a semiconductor device according to embodiments of the inventive concept. To simplify explanation, descriptions of configurations that are identical or similar to those previously described may be omitted.

Referring to FIG. 13, a capacitor US may include a metal layer 92 on or covering the upper electrode TE. For example, the metal layer 92 may cover the upper surface of the upper electrode TE but may not cover the sidewall of the upper electrode TE. That is, the second portion TP2 of the upper electrode TE may be free of the metal layer 92. The metal layer 92 may include a metal material such as tungsten.

A mask insulating pattern 83 may be provided on the metal layer 92. The cell contact plug 71 may penetrate the mask insulating pattern 83 and may be connected to the metal layer 92. In some embodiments, the cell contact plug may extend through the metal layer 92 to directly contact the upper electrode TE.

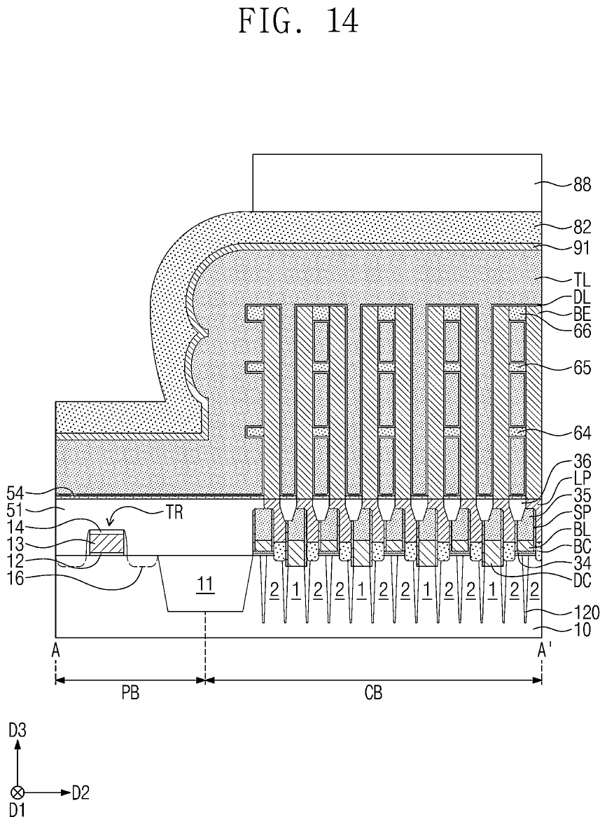

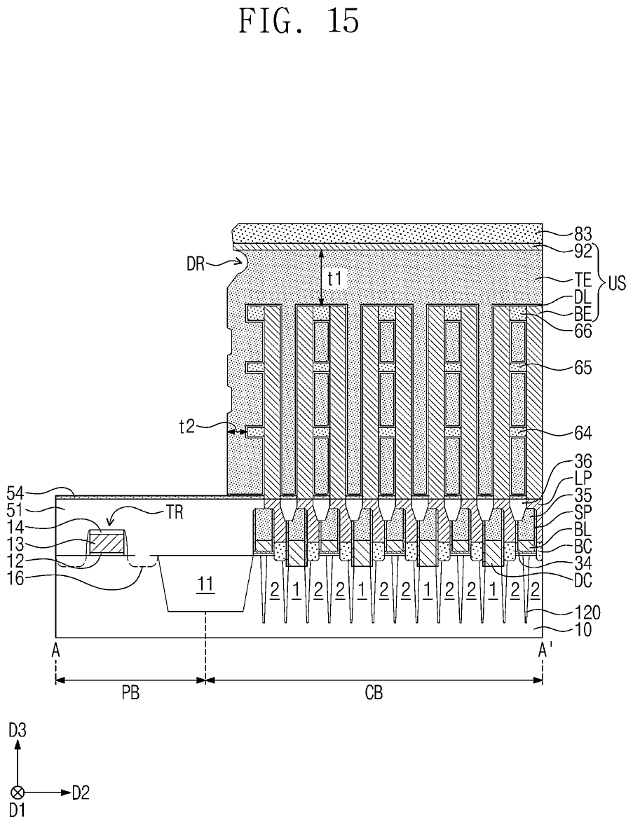

FIGS. 14 and 15 are cross-sectional views for illustrating a method of manufacturing a semiconductor device according to embodiments of the inventive concept.

Referring to FIG. 14, a preliminary metal layer 91, a mask insulating layer 82, and a photo resist pattern 88 may be sequentially formed on the result described with reference to FIG. 8. The preliminary metal layer 91 may be formed on the cell region CB and the peripheral circuit region PB. Referring to FIG. 15, the mask insulating layer 82 may be patterned using the photoresist pattern 88 as an etch mask to form the mask insulating pattern 83. The preliminary metal layer 91 may be patterned using the mask insulating pattern 83 as an etch mask to form a metal layer 92. Afterwards, the etching process for the upper electrode layer TL described with reference to FIG. 10 may be performed to form the upper electrode TE. Thereafter, the process of forming the cell contact plug 71, the peripheral contact plug 72, the first wiring 74, and the second wiring 75 described with reference to FIG. 3 may be performed.

According to embodiments of the inventive concept, the sidewall portion of the upper electrode may be formed to be thinner to secure and increase or maximize the separation distance between the peripheral contact plug and the upper electrode, thereby improving the electrical characteristics of the semiconductor device and increasing the integration.

It will be understood that spatially relative terms such as ‘top,’ ‘above,’ ‘upper,’ ‘upper portion,’ ‘upper surface,’ ‘bottom,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

While embodiments are described above, a person skilled in the art may understand that many modifications and variations are made without departing from the scope of the inventive concept defined in the following claims. Accordingly, the example embodiments of the inventive concept should be considered in all respects as illustrative and not restrictive, with the scope of the inventive concept being indicated by the appended claims.

What is claimed is:

1. A semiconductor device comprising:
lower electrodes on a substrate;
a support pattern between the lower electrodes;
an upper electrode on the lower electrodes and the support pattern; and
a dielectric layer between the lower electrodes and the upper electrode, and between the support pattern and the upper electrode,
wherein the upper electrode comprises:
a first portion on upper surfaces of the lower electrodes; and
a second portion on a sidewall of the support pattern, and
wherein the first portion is thicker than the second portion.

2. The semiconductor device of claim 1, wherein the second portion has a thickness that is about 50% to about 90% of a thickness of the first portion.

3. The semiconductor device of claim 1, wherein the first portion comprises a dent region having a concave shape adjacent to the second portion.

4. The semiconductor device of claim 1, further comprising:
a mask insulating pattern on the first portion of the upper electrode opposite the lower electrodes; and
an interlayer insulating layer on the mask insulating pattern,
wherein the mask insulating pattern includes a material having etch selectivity with a material of the interlayer insulating layer.

5. The semiconductor device of claim 4, wherein the first portion comprises a dent region having a concave shape adjacent to the second portion, and
wherein the dent region undercuts the mask insulating pattern.

6. The semiconductor device of claim 4, wherein the mask insulating pattern has a thickness smaller than a thickness of the first portion.

7. The semiconductor device of claim 4, wherein the mask insulating pattern has a thickness smaller than a thickness of the second portion.

8. The semiconductor device of claim 1, wherein the semiconductor device comprises a cell region and a peripheral circuit region,
wherein the upper electrode is in the cell region,
wherein the peripheral circuit region comprises a peripheral transistor and a peripheral contact plug electrically connected to the peripheral transistor, and
wherein the second portion is between the peripheral contact plug and the support pattern.

9. The semiconductor device of claim 8, wherein a distance between the second portion and the peripheral contact plug is greater than a thickness of the first portion.

10. The semiconductor device of claim 1, further comprising:
a metal layer on the first portion opposite the lower electrodes.

11. The semiconductor device of claim 10, wherein the semiconductor device comprises a cell region and a peripheral circuit region,
wherein the upper electrode is in the cell region,
wherein the metal layer comprises a protrusion extending toward a peripheral contact plug that is electrically connected to a peripheral transistor in the peripheral circuit region, and
wherein a distance between the second portion and the peripheral contact plug is greater than a distance between the protrusion and the peripheral contact plug.

12. A semiconductor device comprising:
lower electrodes on a substrate;
a support pattern between the lower electrodes;
an upper electrode on the lower electrodes and the support pattern;
a dielectric layer between the lower electrodes and the upper electrode, and between the support pattern and the upper electrode; and
a mask insulating pattern on the upper electrode opposite the lower electrodes and the support pattern,
wherein the upper electrode comprises:
a first portion on upper surfaces of the lower electrodes; and
a second portion on a sidewall of the support pattern, and
wherein the mask insulating pattern is thinner than the first portion.

13. The semiconductor device of claim 12, wherein the second portion has a thickness that is about 50% to about 90% of a thickness of the first portion.

14. The semiconductor device of claim 12, wherein the first portion comprises a dent region having a concave shape adjacent to the second portion.

15. The semiconductor device of claim 12, further comprising an interlayer insulating layer on the mask insulating pattern,
wherein the mask insulating pattern includes a material having etch selectivity with a material of the interlayer insulating layer.

16. The semiconductor device of claim 12, wherein the first portion comprises a dent region having a concave shape adjacent to the second portion, and
wherein the dent region undercuts the mask insulating pattern.

17. The semiconductor device of claim 12, wherein the mask insulating pattern has a thickness smaller than a thickness of the second portion.

18. The semiconductor device of claim 12, wherein the semiconductor device comprises a cell region and a peripheral circuit region,
wherein the upper electrode is in the cell region,
wherein the peripheral circuit region comprises a peripheral transistor and a peripheral contact plug electrically connected to the peripheral transistor, and
wherein the second portion is between the peripheral contact plug and the support pattern.

19. The semiconductor device of claim 18, wherein a distance between the second portion and the peripheral contact plug is greater than a thickness of the first portion and is greater than a thickness of the mask insulating pattern.

20. A semiconductor device, comprising:
active regions defined on a substrate by a device isolation layer, the active regions respectively comprising a first impurity region and a second impurity region;
word lines on the active regions and extending in a first direction;
capping insulating patterns on top surfaces of the word lines, respectively;
bit lines on the word lines and extending in a second direction intersecting the first direction;
contact plugs between the bit lines and electrically connected to the second impurity region; and
a capacitor on the contact plugs,
wherein the capacitor comprises:
lower electrodes on the substrate;
a support pattern between the lower electrodes;
an upper electrode on the lower electrodes and the support pattern; and
a dielectric layer between the lower electrodes and the upper electrode, and between the support pattern and the upper electrode,
wherein the upper electrode comprises:
a first portion on upper surfaces of the lower electrodes; and
a second portion on a sidewall of the support pattern, and
wherein the first portion is thicker than the second portion.
